(19) United States
(12) Patent Application Publication
(10) Pub. No.: US 2024/0118354 A1
(43) Pub. Date: Apr. 11, 2024

(54) COMPENSATING A HARMONIC

(71) Applicant: TDK - Micronas GmbH, Freiburg (DE)

(72) Inventors: Jörg Franke, Freiburg (DE); David Muthers, Freiburg (DE)

(21) Appl. No.: 18/376,886

(22) Filed: Oct. 5, 2023

(30) Foreign Application Priority Data
Oct. 6, 2022 (DE) 10 2022 125 821.1

(51) Int. Cl. G01R 33/09

(52) U.S. Cl. CPC G01R 33/09

(57) ABSTRACT

A device and a method for compensating a harmonic in an output voltage of at least one xMR sensor assembly is provided. The device includes the at least one xMR sensor assembly including at least one magnetoresistive element, at least one excitation magnet, at least one demodulation unit, a scaling unit and a superposing unit. The method includes detecting the output voltage of the at least one xMR sensor assembly in a demodulation unit, converting the output voltage of the at least one xMR sensor assembly in the demodulation unit, generating a compensation voltage from the demodulation voltage in a scaling unit, and superposing the compensation voltage with the output voltage of the at least one xMR sensor assembly in a superposing unit.

### CROSS-REFERENCE TO RELATED APPLICATIONS

This application claims benefit of and priority to German patent application DE 10 2022 125 821.1, filed on 6 Oct. 2022. The entire disclosure of German patent application DE 10 2022 125 821.1 is hereby incorporated by reference herein.

### FIELD OF TECHNOLOGY

The following relates to a method and apparatus for compensating a harmonic in an output voltage of a magnetoresistive element.

### BACKGROUND

By applying a magnetic field to specially layered materials, an electrical resistance of these materials or structures can be changed. This change in the electrical resistance of the conductor is based on so-called magnetoresistive effects. In modern sensor assemblies, these magnetoresistive effects are used to determine a variety of different parameters. In most applications, the magnetic field is used as an intermediate variable to realize various position or displacement measurement systems, which can also include angle and rate of rotation. These sensor assemblies usually include at least one magnetoresistive element (often referred to as “xMR” element). These sensor assemblies are therefore often referred to as xMR sensor assemblies. The magnetoresistive element comprises at least a barrier layer, a fixed layer and a free layer. The barrier layer is arranged between the free layer and the fixed layer. The magnetoresistive element can be designed, for example, as a tunnel magnetoresistance (often also referred to as “TMR element” or “TMR”) or as a giant magnetoresistance (often also referred to as “GMR element” or “GMR”).

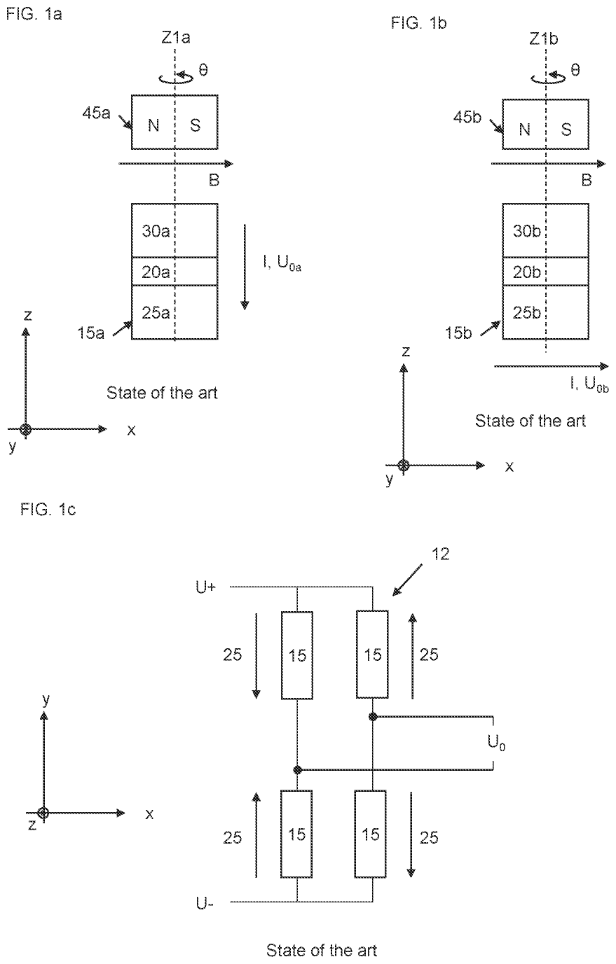

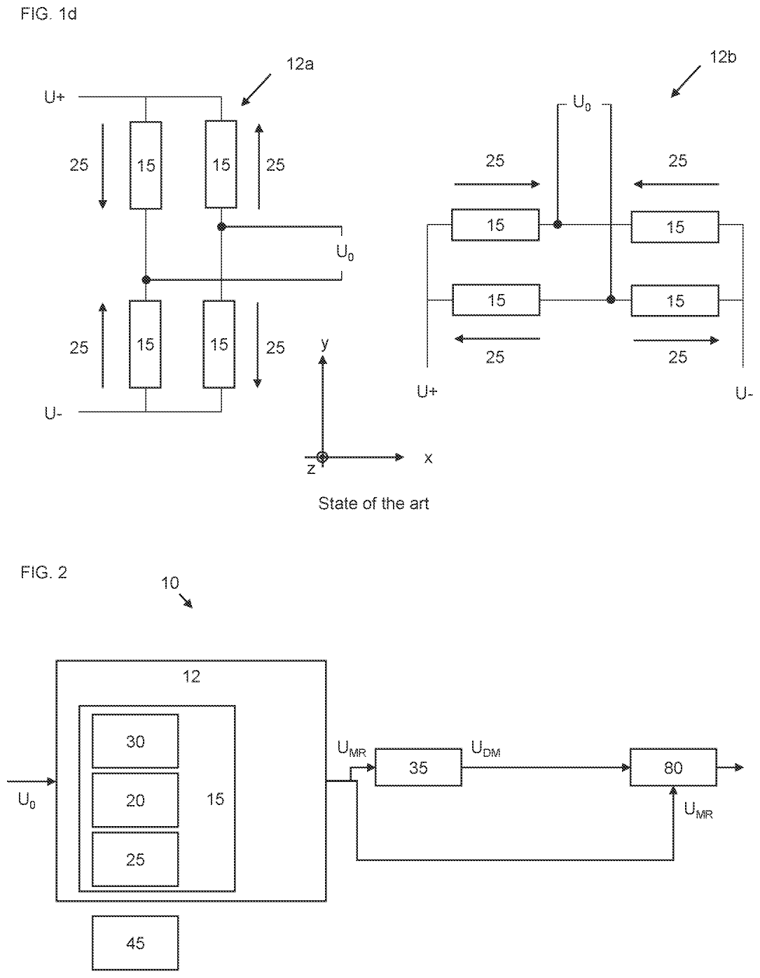

FIG. 1a shows a known schematic structure of a TMR element 15a. The TMR element 15a includes a barrier layer 20a, a fixed layer 25a, and a free layer 30a. The barrier layer 20a is arranged between the free layer 30a and the fixed layer 25a. The TMR element 15a is excited by an excitation magnet 45a. The barrier layer 20a, the free layer 30a, the fixed layer 25a, and the excitation magnet 45a are arranged along an axis Z1a. The axis Z1a extends parallel to a z-axis of a base coordinate system. The excitation magnet 45a has at least one magnetic field having a north pole N and a south pole S. The excitation magnet 45a is arranged to be rotatable about the axis Z1a. The free layer 30a is made of a ferromagnetic material. A magnetization direction of the free layer 30a of the TMR element 15a follows the orientation of the magnetic field of the excitation magnet 45a. The fixed layer 25a is made of a permanent magnetic material. A magnetization direction of the fixed layer 25a is substantially fixed. In the TMR element 15a, the barrier layer 20a is formed as an electrically conductive material. In the TMR element 15a, the input voltage U₀ₐ is applied parallel to the axis Z1a.

FIG. 1b shows a known schematic structure of a GMR element 15b. The GMR element 15b includes a barrier layer 20b, a fixed layer 25b, and a free layer 30b. The barrier layer 20b is arranged between the free layer 30b and the fixed layer 25b. The GMR element 15b is excited by an excitation magnet 45b. The barrier layer 20b, the free layer 30b, the fixed layer 25b, and the excitation magnet 45b are arranged along an axis Z1b. The axis Z1b extends parallel to the z-axis of the base coordinate system. The excitation magnet 45b has at least one magnetic field having a north pole N and a south pole S. The excitation magnet 45b is arranged to be rotatable about the axis Z1b. The free layer 30b is made of a ferromagnetic material. A magnetization direction of the free layer 30a of the GMR element 15b follows the orientation of the magnetic field of the excitation magnet 45b. The fixed layer 25b is made of a permanent magnetic material. A magnetization direction of the fixed layer 25b is substantially fixed. In the GMR element 15b, the input voltage Uob is applied orthogonally to the axis Z1.

Due to the rotation of the excitation magnet 45a, 45b about the axis Z1a, Z1b, a change in an arrangement of magnetic fields of the free layer 30a, 30b relative to the fixed layer 25a, 25b occurs in the TMR element 15a and the GMR element 15b. Here, the magnetic field of the free layer 30a, 30b follow the excitation by the excitation magnet 45a, 45b, as mentioned above. If the input voltage U₀ is applied to the magnetoresistive element 15, comprising the TMR element 15a and the GMR element 15b, while the excitation magnet 45 rotates about the axis Z1, a so-called “TMR effect” occurs in the TMR element, whereas a so-called “GMR effect” occurs in the GMR element 15b.

FIG. 1c shows an xMR sensor assembly 12. The xMR sensor assembly 12 typically comprises at least four magnetoresistive elements 15 spaced apart from each other, which are interconnected in a Wheatstone bridge and often also referred to as an xMR bridge. The magnetoresistive elements 15 may be, for example, TMR elements 15a or GMR elements 15b. When TMR elements 15a are used in the Wheatstone bridge, they are also referred to as a TMR sensor assembly 12 or a TMR bridge 12.

When GMR elements 15b are used in the Wheatstone bridge, it is also referred to as a GMR sensor assembly 12 or a GMR bridge 12. The xMR sensor assembly 12 is arranged along an x-axis of the base coordinate system or a y-axis of the base coordinate system. The x-axis is orthogonal to the y-axis. The x-axis and the y-axis are orthogonal to the z-axis of the base coordinate system.

Furthermore, FIG. 1c illustrates an orientation of the fixed layer 25 25 having a magnetic field with the indicated orientation at each of the four magnetoresistive elements 15. The orientation of the fixed layer 25 is dependent on an orientation of the excitation magnet 45.

The Wheatstone bridge is formed by a parallel connection of at least two magnetoresistive elements 15 in series with each other. The input voltage U₀ is applied to the Wheatstone bridge. The occurrence of the magnetoresistive effects changes an electrical resistance of the magnetoresistive elements 15 connected in the Wheatstone bridge. In addition to the changing of the resistance of the magnetoresistive elements 15, (the) harmonic(s) occur(s) in the output voltage U_{MR} of the magnetoresistive elements 15 when measuring the rotational position or orientation of the excitation magnet Z1 when the magnetoresistive elements 15 are connected in the Wheatstone bridge. In this context, the harmonic designates an upper harmonic or an upper wave whose frequency is an integral multiple of a fundamental frequency of the input voltage U₀.

In an embodiment, two xMR sensor assemblies 12a, 12b can be arranged offset or rotated by essentially 90° (ninety degrees) relative to each other. This allows to obtain two phase-shifted signals (cosine, sine). FIG. 1d shows such a configuration in which two xMR sensor assemblies 12a, 12b are arranged rotated by essentially 90°. Each of the xMR sensor assemblies 12a, 12b comprises at least four magnetoresistive elements 15 spaced apart from each other, which are interconnected in Wheatstone bridge. Accordingly, FIG. 1d shows an arrangement of two xMR sensor assemblies 12a, 12b (also referred to as two xMR bridges 12a, 12b), which are arranged rotated by substantially 90° relative to each other. For example, the first xMR sensor assembly 12a is arranged along the x-axis and the second xMR sensor assembly 12b is arranged along the y-axis.

Furthermore, FIG. 1d illustrates the orientation of the fixed layer 25 at each of the eight magnetoresistive elements 15. The orientation of the fixed layer 25 is dependent on an orientation of the excitation magnet 45.

The harmonic is caused by anon-ideal property of the fixed layer 25, which can be described by a non-negligible magnetizability of the fixed layer 25. This non-negligible magnetizability results in a magnetic field component of the fixed layer 25, which is determined orthogonal to the orientation of the fixed layer 25. An occurrence of the harmonic with respect to the excitation magnet is, among others, dependent on amplitude and direction, with the maximum of the direction dependence occurring at orthogonal alignment of an excitation field generated by the excitation magnet 45 and the alignment of a magnetic field of the fixed layer 25.

As a result, the harmonic(s) occur(s) in the output voltage U_{MR} of the xMR sensor assembly 12. In the conventional art, a compensating of the harmonic(s) is performed by a downstream processor assembly, which calibrates an excitation magnet used in the final application with respect to its angular position. However, there are no known solutions that compensate the harmonic without a separate downstream processor module and, for example, taking amplitude and temperature into account.

### SUMMARY

An aspect relates to a method and a device to compensate for a distortion of the output signal due to the occurrence of a harmonic. In light of this background, a method and a device are provided for compensating a harmonic in an output voltage of at least one xMR sensor assembly by generating the harmonic by demodulation from the output voltage and weighting or scaling them by a scaling unit. In embodiments, the method comprises detecting the output voltage of the at least one xMR sensor assembly in a demodulation unit, the at least one xMR sensor assembly comprising at least one magnetoresistive element, converting the output voltage of the at least one xMR sensor assembly in the demodulation unit, generating a compensation voltage from the demodulation voltage in the scaling unit, and compensating the harmonic by superposing the compensation voltage with or on the output voltage of the at least one xMR sensor assembly in a superposing unit. Converting the output voltage further comprises generating a demodulation voltage. The generation of the compensation voltage from the demodulation voltage in the scaling unit is performed using a scaling parameter. Superposing the compensation voltage with or on the output voltage of the at least one xMR sensor assembly is performed in the superposing unit.

In embodiments, the method allows to compensate the harmonic in the output voltage.

In one aspect, the method further comprises determining the scaling parameter.

Determining the scaling parameter allows the compensation voltage to be flexibly determined from the demodulation voltage.

In another aspect, the method comprises determining the scaling parameter using an amplitude unit.

Determining the scaling parameter using the amplitude unit allows the compensation voltage to be flexibly determined from the demodulation voltage.

In another aspect, in the method, determining the scaling parameter comprises comparing a first magnetic field strength and/or a second magnetic field strength. The first magnetic field strength is sensed or determined by a first Hall sensor. The second magnetic field strength is sensed or determined by a second Hall sensor.

Using the amplitude unit to determine the first magnetic field strength and the second magnetic field strength allows the scaling parameter to be flexibly determined as a function of the sensed first magnetic field strength and/or second magnetic field strength.

In another aspect, in the method, determining the scaling parameter is performed using the temperature unit. The determining of the scaling parameter comprises determining a temperature of at least one of the at least one xMR sensor assembly.

Determining a scaling parameter using the temperature unit allows the scaling parameter to be determined in a flexible manner.

In another aspect, in the method, determining the temperature of at least one of the at least one xMR sensor assembly comprises sensing a temperature of the magnetoresistive element, wherein the sensing of the temperature of the magnetoresistive element comprises sensing a temperature of at least one of a barrier layer, a fixed layer, or a free layer of the magnetoresistive element.

Using the temperature unit to determine the temperature of at least one of the at least one xMR sensor assembly comprising the magnetoresistive element(s) allows the scaling parameter to be flexibly determined as a function of the sensed temperature of at least one of the barrier layers, the fixed layer, or the free layer of the magnetoresistive element(s).

In another aspect, a method for compensating a harmonic in an output voltage of at least one xMR sensor assembly comprises detecting the output voltage of the at least one xMR sensor assembly in a demodulation unit, converting the output voltage of the at least one xMR sensor assembly in the demodulation unit, and compensating the harmonic by superposing the demodulation voltage with or on the output voltage of the at least one xMR sensor assembly in a superposing unit. The converting further comprises generating a demodulation voltage.

In embodiments, the method allows to compensate the harmonic in the output voltage.

In another aspect, a device for compensating a harmonic in the output voltage of the at least one xMR sensor assembly comprises the at least one xMR sensor assembly comprising at least one magnetoresistive element, at least one excitation magnet, at least one demodulation unit, a scaling unit, and a superposing unit. The at least one magnetoresistive element comprises a barrier layer, a fixed layer, and a free layer. The barrier layer of the magnetoresistive element is arranged between the free layer and the fixed layer. The at least one xMR sensor assembly further has the output voltage. The at least one demodulation unit is electrically connected to the at least one xMR sensor assembly. The demodulation unit is arranged to demodulate the output voltage of the at least one xMR sensor assembly, thereby generating a demodulation voltage. More specifically, the demodulation unit is arranged to generate the demodulation voltage by converting the output voltage of the at least one xMR sensor assembly. The scaling unit is electrically connected to the demodulation unit. The scaling unit is arranged to generate a compensation voltage using a scaling parameter. The superposing unit is electrically connected to the at least one xMR sensor assembly and the scaling unit. The superposing unit is arranged to superpose or overlay or mathematically add the compensation voltage with or on the output voltage of the at least one xMR sensor assembly.

The device allows to compensate the harmonic in the output voltage.

In another aspect, the barrier layer, the fixed layer, and the free layer are arranged along an axis. Further, the excitation magnet is arranged along the axis.

The arrangement of the barrier layer, the fixed layer, and the free layer along the axis allows the device to be compact.

In another aspect, in the device, the fixed layer comprises a ferromagnet.

In one aspect, the configuration of the fixed layer allows the device to be compact.

In another aspect, in the device, the free layer comprises a permanent magnet.

In one aspect, the configuration of the free layer allows the device to be compact.

In another aspect, in the device, the excitation magnet is arranged to rotate about or is arranged to be rotatable about an axis relative to the at least one xMR sensor assembly.

The arrangement of the excitation magnet allows interactions to be generated with the free layer of the magnetoresistive element of the at least one xMR sensor assembly.

In another aspect, in the device, the at least one demodulation unit comprises a plurality of separate demodulation units.

The configuration of the device comprising a plurality of separate demodulation units allows for compensating of a harmonic of different frequencies.

In another aspect, the device has a fixed scaling parameter, or a scaling parameter being fixedly defined.

The configuration of the device having the fixed scaling parameter allows the harmonic to be suitably compensated for a plurality of use cases.

In another aspect, in the device, the scaling parameter is variable. Further, the scaling unit determines the scaling parameter using at least one of an amplitude unit and a temperature unit.

In another aspect, the device having the variable scaling parameter allows the harmonic to be suitably compensated depending on using the amplitude unit and/or the temperature unit.

In another aspect, in the device, the amplitude unit comprises at least a first Hall sensor and a second Hall sensor.

The configuration of the device comprising the first Hall sensor and the second Hall sensor allows the scaling parameter to be flexibly determined as a function of the sensed first magnetic field strength and/or the sensed second magnetic field strength.

In another aspect, a device for compensating a harmonic in the output voltage of the at least one xMR sensor assembly comprises the at least one xMR sensor assembly, at least one excitation magnet, at least one demodulation logic, a scaling logic, and a superposing logic. The at least one xMR sensor assembly comprises at least one magnetoresistive element, at least one excitation magnet, at least one demodulation unit, a scaling unit, and a superposing unit. The at least one magnetoresistive element comprises a barrier layer, a fixed layer, and a free layer. The barrier layer of the magnetoresistive element is arranged between the free layer and the fixed layer. The at least one xMR sensor assembly further has the output voltage. The at least one demodulation logic is logically connected to the at least one xMR sensor assembly. The demodulation logic is arranged to generate a demodulation voltage by converting the output voltage of the at least one xMR sensor assembly. The scaling logic is logically connected to the demodulation logic. The scaling logic is arranged to generate a compensation voltage using a scaling parameter. The superposing logic is logically connected to the at least one xMR sensor assembly and the scaling logic. The superposing logic is arranged to overlay the compensation voltage with the output voltage of the at least one xMR sensor assembly.

The configuration of the device comprising the at least one xMR sensor assembly, the at least one excitation magnet, the at least one demodulation logic, the scaling logic, and the superposing logic allows for compensating of the harmonic.

In another aspect, a computer-implemented method for compensating a harmonic in an output voltage of at least one xMR sensor assembly by a scaling logic comprises detecting the output voltage of the at least one xMR sensor assembly comprising at least one magnetoresistive element in a demodulation logic, converting the output voltage of the at least one xMR sensor assembly in the demodulation logic, generating a compensation voltage from the demodulation voltage in the scaling unit, compensating the harmonic by superposing the compensation voltage on the output voltage of the at least one xMR sensor assembly in a superposing logic. The converting comprises generating a demodulation voltage. The generating of the compensation voltage is performed using a scaling parameter.

In embodiments, the method allows to compensate the harmonic in the output voltage.

In another aspect, a computer-implemented method for compensating a harmonic in an output voltage of at least one xMR sensor assembly comprises detecting the output voltage of the at least one xMR sensor assembly comprising at least one magnetoresistive element in a demodulation logic, converting the output voltage of the at least one xMR sensor assembly in the demodulation logic, and compensating the harmonic by superposing the demodulation voltage with the output voltage of the at least one xMR sensor assembly in a superposing logic. The converting comprises generating a demodulation voltage.

In embodiments, the method allows to compensate the harmonic in the output voltage.

### BRIEF DESCRIPTION

Some of the embodiments will be described in detail, with reference to the following figures, wherein like designations denote like members, wherein:

FIG. 1a shows a schematic structure of a TMR element;

FIG. 1b shows a schematic structure of a GMR element;

FIG. 1c shows a schematic structure of a Wheatstone bridge;

FIG. 1d shows an arrangement of two xMR sensor assemblies;

FIG. 2 shows a first configuration of a device for compensating of a harmonic in an output voltage of at least one xMR sensor assembly;

FIG. 3 shows a second configuration of a device for compensating of the harmonic in the output voltage of the at least one xMR sensor assembly;

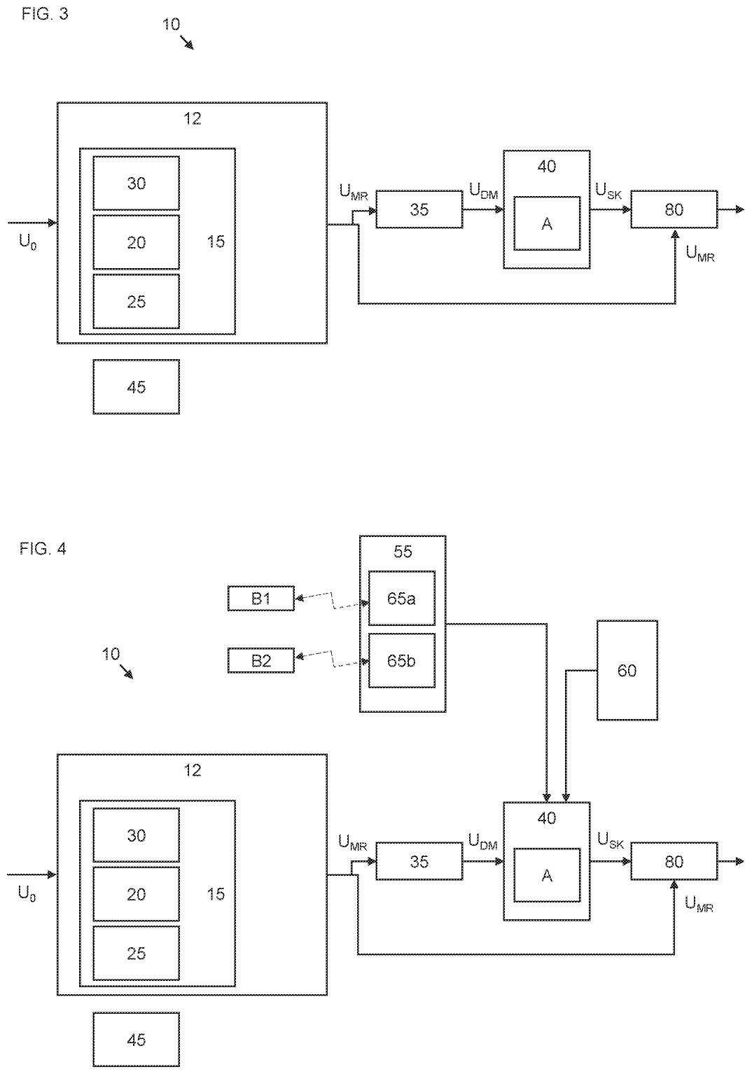

FIG. 4 shows a third configuration of a device for compensating the harmonic in the output voltage of the at least one xMR sensor assembly;

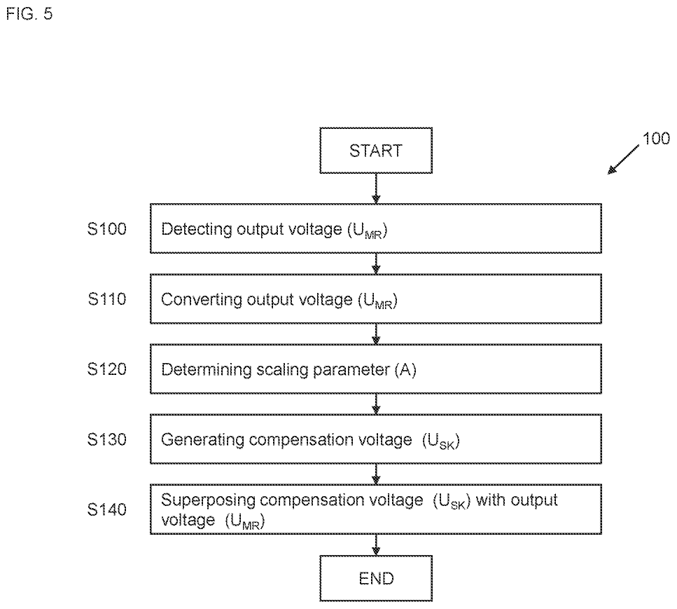

FIG. 5 shows a process flow diagram depicting a method for compensating the harmonic in the output voltage of the at least one xMR sensor assembly;

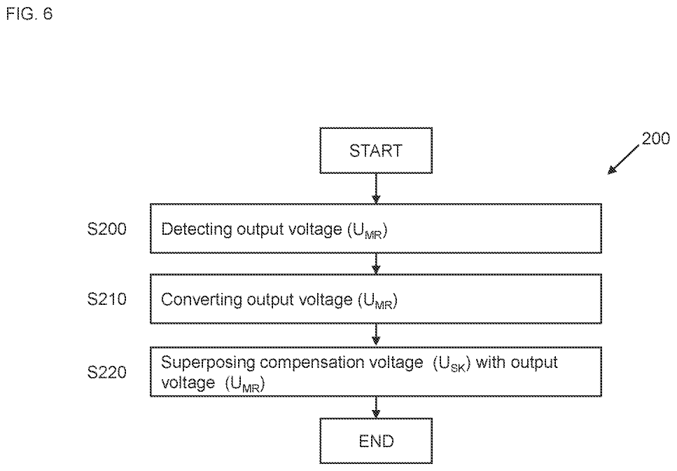

FIG. 6 shows a process flow diagram depicting a method for compensating the harmonic in the output voltage of the at least one xMR sensor assembly.

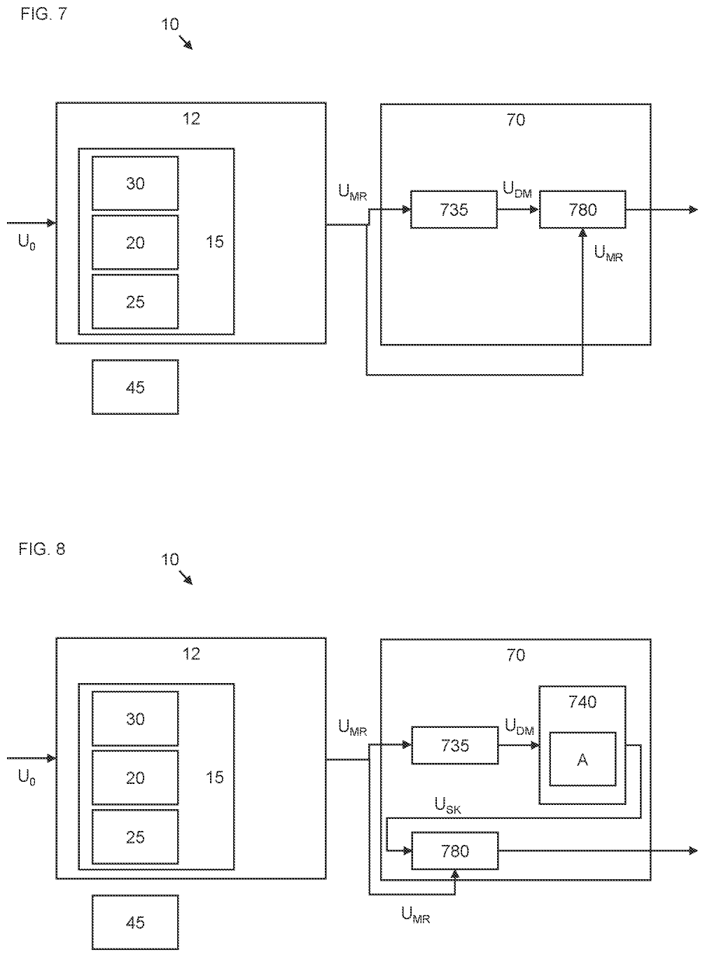

FIG. 7 shows a fourth configuration of a device for compensating the harmonic in the output voltage of the at least one xMR sensor assembly;

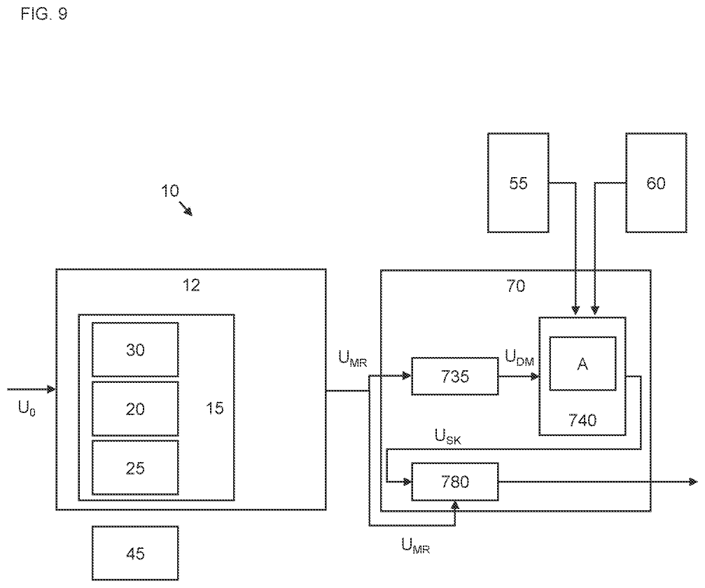

FIG. 8 shows a fifth configuration of a device for compensating the harmonic in the output voltage of the at least one xMR sensor assembly;

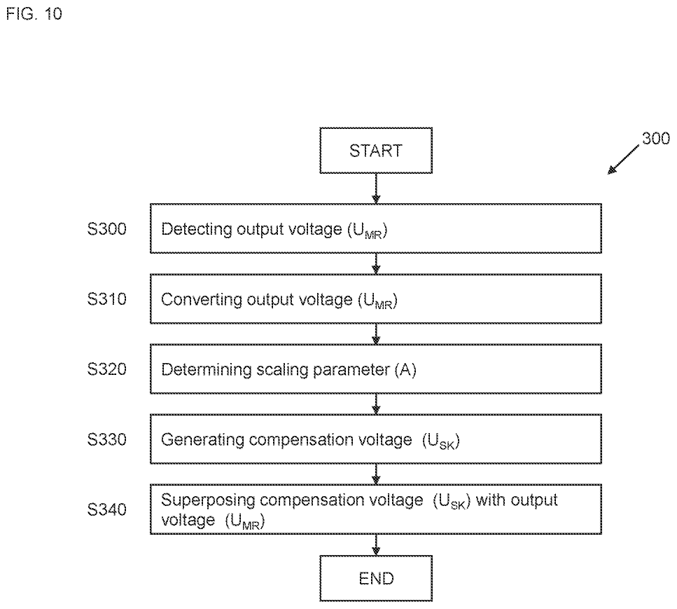

FIG. 9 shows a sixth configuration of a device for compensating the harmonic in the output voltage of the at least one xMR sensor assembly;

FIG. 10 shows a process flow diagram depicting a method for compensating the harmonic in the output voltage of the at least one xMR sensor assembly; and

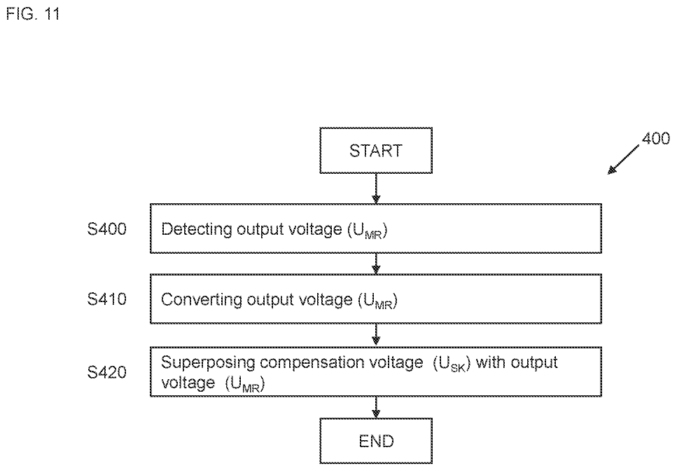

FIG. 11 shows a process flow diagram depicting a method for compensating the harmonic in the output voltage of the at least one xMR sensor assembly.

### DETAILED DESCRIPTION

FIG. 2 shows a schematic diagram of a first configuration of a device 10 for compensating a harmonic in an output voltage U_{MR} of at least one xMR sensor assembly 12. The device 10 comprises the at least one xMR sensor assembly 12, at least one demodulation unit 35, at least one excitation magnet 45, and a superposing unit 80. The at least one xMR sensor assembly 12 comprises at least one magnetoresistive element 15. In an embodiment, the xMR sensor assembly 12 comprises at least four magnetoresistive elements 15 spaced apart from each other, which are interconnected in a Wheatstone bridge. These at least four magnetoresistive elements 15 are substantially identical and will accordingly be referred to hereinafter only as magnetoresistive elements 15. In an embodiment, the device 10 comprises two xMR sensor assemblies 12a, 12b. The two xMR sensor assemblies 12a, 12b are substantially identical to each other and accordingly correspond to the xMR sensor assembly 12. However, the two xMR sensor assemblies 12a, 12b are rotated by substantially 90° relative to each other. This rotation by substantially 90° allows to obtain two out-of-phase signals (cosine, sine).

The magnetoresistive element 15 includes a barrier layer 20, a fixed layer 25, and a free layer 30. The barrier layer 20 is arranged between the free layer 30 and the fixed layer 25. The xMR sensor assembly 12 is excited by an excitation magnet 45. The barrier layer 20, the fixed layer 25, the free layer 30, and the excitation magnet 45 are arranged along an axis Z1. The excitation magnet 45b has at least one magnetic field with a north pole N and a south pole S. The excitation magnet 45 is arranged relative to the fixed layer 25. The excitation magnet 45 is arranged to rotate relative to the xMR sensor assembly 12 about the axis Z1. The free layer 30 is made of a ferromagnetic material. A magnetization direction of the free layer 30 of the magnetoresistive element 15 follows the orientation of the magnetic field of the excitation magnet 45. The fixed layer 25 is made of a permanent magnetic material. A magnetization direction of the fixed layer 25 is substantially fixed.

The xMR sensor assembly 12 includes at least one of the TMR element 15a or the GMR element 15b. The input voltage U₀ is applied to the xMR sensor assembly 12. The xMR sensor assembly 12 further comprises the output voltage U_{MR}. In the xMR sensor assembly 12, a rotation of the excitation magnet 45 about the axis Z1 causes a change in an arrangement of magnetic fields of the free layer 30 relative to the fixed layer 25. As a result, the TMR effect and the GMR effect occur, respectively. Due to these magnetoresistive effects, the harmonic(s) occur in the output voltage U_{MR} of the xMR sensor assembly 12.

The occurrence of the harmonic in the output voltage U_{MR} of the xMR sensor assembly 12 depends on a rotation angle θ of the excitation magnet 45 relative to that of the xMR sensor assembly 12 about the axis Z1. An amplitude of the harmonic in the output voltage U_{MR} can be approximated by the following equations. An observation, separately for sine curve and cosine curve, can be expressed as shown below.

U_{MR} sin′ θ=U_{MR} sin(θ+U_{MR} sin(2*θ))

U_{MR} cos′ θ=U_{MR} cos θ+U_{MR} cos(2*θ))

To compensate the harmonic, the demodulation unit 35 is electrically connected to the xMR sensor assembly 12. The demodulation unit 35 is arranged to generate a correction signal in the form of a demodulation voltage U_{DM} from the output voltage U_{MR} of the xMR sensor assembly 12. In the demodulation unit 35, the output voltage U_{MR} of the xMR sensor assembly 12 is converted. This conversion comprises a generation of the demodulation voltage U_{DM}. The demodulation unit 35 may be a single demodulation unit 35 or may comprise a plurality of separate demodulation units 35 that are electrically interconnected. By using a plurality of demodulation units 35, it is possible, for example, to compensate the harmonic of different frequencies.

In the first configuration of the device 10, the compensating of the harmonic is performed by summing up or (mathematically) adding the demodulation voltage U_{DM} and the output voltage U_{MR} in the superposing unit 80. For this compensating of the harmonic, the superposing unit 80 is electrically connected to the xMR sensor assembly 12. The superposing unit 80 is arranged to superpose the demodulation voltage U_{DM} with the output voltage U_{MR} of the xMR sensor assembly 12 and thereby compensating the harmonic. The superposing unit 80 comprises, for example, a so-called Gilbert cell (often referred to as a “gilbert cell” or “gilbert multiplier”).

FIG. 3 shows a schematic representation of a second configuration of the device 10. In this second configuration, the device 10 comprises substantially the components of the first configuration and further comprises at least one scaling unit 40. This scaling unit 40 is electrically connected to the at least one demodulation unit 35 for compensating the harmonic in the output voltage U_{MR} of the xMR sensor assembly 12. In this second configuration, the compensating of the harmonic is performed using a scaling parameter A.

The occurrence of the harmonic in the output voltage U_{MR} of the xMR sensor assembly 12 is dependent on the rotation angle θ of the excitation magnet 45 relative to the xMR sensor assembly 12 about the axis Z1, as already described in the first configuration of the device. The amplitude of the harmonic in the output voltage U_{MR} can be approximated by the following equations. An observation, separately for sine curve and cosine curve, may be expressed as shown below, where A in this second configuration describes the scaling parameter A.

U_{MR} sin′ θ=U_{MR} sin(θ+A*U_{MR} sin(2*θ))

U_{MR} cos′ θ=U_{MR} cos θ+A*U_{MR} cos(2*θ))

Further, to compensate the harmonic, the scaling unit 40 is electrically connected to the demodulation unit 35. The scaling unit 40 is arranged to generate a compensation voltage U_{SK} from the demodulation voltage U_{DM} of the demodulation unit 35 using the scaling parameter A.

The scaling parameter A may be fixed or variable. In the second configuration of the device 10 shown in FIG. 3, the scaling parameter A is variable. In the second configuration, the scaling parameter A is determined using a reference table. The reference table includes a plurality of fixedly defined values in the form of a table. For example, the reference table for the demodulation voltage U_{DM} determined by the demodulation unit 35 may contain a corresponding value of the scaling parameter A. This allows to determine the scaling parameter A from the determined demodulation voltage U_{DM}. If the determined value of the demodulation voltage U_{DM} is between or outside the values defined in the reference table, the scaling parameter A is determined, for example, by interpolation from the determined demodulation voltage U_{DM}. The interpolation can, for example, be a linear interpolation between values defined in the reference table. However, higher degree polynomials, a trigonometric interpolation, or even a logarithmic interpolation can also be used in the interpolation, for example.

Based on the scaling parameter A determined by the scaling unit 40, the compensation voltage U_{SK} is generated by the scaling unit 40 from the demodulation voltage U_{DM}. For compensating of the harmonic, the superposing unit 80 is electrically connected to the xMR sensor assembly 12 and the scaling unit 40. The superposing unit 80 is arranged to superpose the compensation voltage U_{SK} on the output voltage U_{MR} of the xMR sensor assembly 12, thereby compensating the harmonic.

FIG. 4 shows a schematic diagram of a third configuration of the device 10. The device 10 of the third configuration further comprises at least one of an amplitude unit 55 and a temperature unit 60. In this third configuration, the scaling parameter A is variable. In the third configuration, determining the scaling parameter A is performed using the amplitude unit 55 and/or the temperature unit 60.

The amplitude unit 55 comprises at least a first Hall sensor 65a and/or a second Hall sensor 65b. The number of Hall sensors 65a, 65b depends on a number of xMR sensor assemblies 12, 12a, 12b. Provided that the device 10 comprises only one xMR sensor assembly 12, the amplitude unit 55 comprises only one of the first Hall sensor 65a or the second Hall sensor 65b. Provided that the device 10 comprises two xMR sensor assemblies 12a, 12b, the amplitude unit 55 comprises the first Hall sensor 65a and the second Hall sensor 65b.

The first Hall sensor 65a determines a magnetic field strength Bₓ of a magnetic field acting or impinging on the xMR sensor assembly 12 in the direction of the x-axis of the base coordinate system. The second Hall sensor 65b determines a magnetic field strength B_{y} of the magnetic field acting on the xMR sensor assembly 12 in the direction of the y-axis of the base coordinate system.

The first Hall sensor 65a and/or the second Hall sensor 65b are arranged on the xMR sensor assembly 12. Where/if the device 10 comprises the first Hall sensor 65a and the second Hall sensor 65b, the first Hall sensor 65a and the second Hall sensor 65b are offset along a plane orthogonal to the axis Z1. The first Hall sensor 65a and/or the second Hall sensor 65b is/are arranged orthogonal to the magnetization direction of the fixed layer 25.

Where the device 10 comprises only one xMR sensor assembly 12, the first Hall sensor 65a or the second Hall sensor 65b is oriented such that it is arranged parallel to the xMR sensor assembly 12. Accordingly, the first Hall sensor 65a or the second Hall sensor 65b detects the magnetic field in the direction of the x-axis or in the direction of the y-axis in which the xMR sensor assembly 12 is arranged.

Provided that the device 10 comprises only a first xMR sensor assembly 12a and a second xMR sensor assembly 12b, the first Hall sensor 65a and the second Hall sensor 65b are oriented such that either the first Hall sensor 65a or the second Hall sensor 65b is parallel to the first xMR sensor assembly 12a and the other of the first Hall sensor 65a and the second Hall sensor 65b is parallel to the second xMR sensor assembly 12b.

The amplitude unit 55 determines an amplitude |B| of the magnetic field acting on the xMR sensor assembly 12 in the x-axis direction and/or the y-axis direction from the magnetic field strength Bₓ determined by the first Hall sensor 65a and/or the magnetic field strength By determined by the second Hall sensor 65b.

The scaling unit 40 uses the amplitude |B| determined by the amplitude unit 55 to determine the scaling parameter A. Based on the scaling parameter A determined by the scaling unit 40, the compensation voltage U_{SK} is generated by the scaling unit 40 from the demodulation voltage U_{DM}. This compensation voltage U_{SK} is superposed by the superposing unit 80 with the output voltage U_{MR} of the xMR sensor assembly 12 being applied to the superposing unit 80. This compensates the harmonic in the output voltage U_{MR} of the xMR sensor assembly 12.

The temperature unit 60 comprises at least one temperature sensor provided on at least one of the barrier layers 20, the fixed layer 25, or the free layer 30 of the magnetoresistive element 15 of the xMR sensor assembly 12. For example, a separate temperature sensor may be provided at or on each of the barrier layer 20, the fixed layer 25, and the free layer 30. For example, a temperature sensor may also be provided at only one of the barrier layers 20, the fixed layer 25, and the free layer 30. For example, multiple temperature sensors may also be provided at one of the barrier layers 20, the fixed layer 25, or the free layer 30. For example, multiple temperature sensors may also be provided at each of the barrier layer 20, the fixed layer 25, and the free layer 30. For example, the temperature sensor(s) may also be spaced apart from each other by the magnetoresistive element 15 of the xMR sensor assembly 12. The temperature sensor(s) of the temperature unit 60 are capable of sensing the temperature of the barrier layer 20, the fixed layer 25, and the free layer 30.

The scaling unit 40 uses the temperature of the barrier layer 20, the fixed layer 25, and/or the free layer 30 sensed by the temperature unit 60 to determine the scaling parameter A. Based on the scaling parameter A determined by the scaling unit 40, the compensation voltage U_{SK} is generated by the scaling unit 40 from the demodulation voltage U_{DM}. This compensation voltage U_{SK} is superposed by the superposing unit 80 with the output voltage U_{MR} of the xMR sensor assembly 12 being applied to the superposing unit 80. This compensates the harmonic in the output voltage U_{MR} of the xMR sensor assembly 12.

The scaling unit 40 may also use the amplitude |B| detected by the amplitude unit 55 and the temperature detected by the temperature unit 60 of at least one of the barrier layer 20, the fixed layer 25, and/or the free layer 30 to determine the scaling parameter A. Based on the scaling parameter A determined by the scaling unit 40, the compensation voltage U_{SK} is generated by the scaling unit 40 from the demodulation voltage U_{DM}. This compensation voltage U_{SK} is superposed by the superposing unit 80 with the output voltage U_{MR} of the xMR sensor assembly 12 being applied to the superposing unit 80.

FIG. 5 illustrates a process flow diagram depicting a method 100 for compensating of a harmonic in the output voltage U_{MR} of the at least one xMR sensor assembly 12 by a scaling unit 40. In embodiments, the method 100 relates to compensating the harmonic by the device 10 according to the second configuration and the third configuration.

In embodiments, the method 100 comprises detecting, in step S100, the output voltage U_{MR} of the xMR sensor assembly 12 in the demodulation unit 35.

In embodiments, the method 100 further comprises converting, in step S110, the output voltage U_{MR} of the xMR sensor assembly 12 in the demodulation unit 35. This converting comprises generating the demodulation voltage U_{DM}.

In embodiments, the method 100 further comprises determining the scaling parameter A in step S120.

In embodiments, the method 100 further comprises generating, in step S130, the compensation voltage U_{SK} from the demodulation voltage U_{DM} in the scaling unit 40. The generating of the compensation voltage U_{SK} in step S120 is performed using a scaling parameter A.

In embodiments, the method 100 further comprises superposing, in step S140, the compensation voltage U_{SK} with the output voltage U_{MR} of the xMR sensor assembly 12 in the superposing unit 80. This superposing in step S140 compensates the harmonic.

FIG. 6 shows a process flow diagram depicting a method 200 for compensating the harmonic in the output voltage U_{MR} of the at least one xMR sensor assembly 12. In embodiments, the method 200 relates to the compensating of the harmonic by the device 10 according to the first configuration.

In embodiments, the method 200 comprises detecting, in step S200, the output voltage U_{MR} of the xMR sensor assembly 12 in the demodulation unit 35.

In embodiments, the method 200 further comprises converting, in step S210, the output voltage U_{MR} of the xMR sensor assembly 12 in the demodulation unit 35. This converting comprises generating the demodulation voltage U_{DM}.

In embodiments, the method 200 further comprises superposing, in step S220, the compensation voltage U_{SK} with the output voltage U_{MR} of the xMR sensor assembly 12 in the superposing unit 80. This superposing, in step S220, compensates the harmonic.

The device 10 and the method 100, 200 for compensating the harmonic in the output voltage U_{MR} of the xMR sensor assembly 12 is, for example, for a use in rotation sensors. The device 10 and the method 100 can increase a starting accuracy of the rotation sensors. This increase in startup accuracy is achieved, for example, by a lower influence of a harmonic/harmonics in a startup of the rotation sensor during the first complete rotation of the rotation sensor. In addition, the device 10 and the method 100 can be used to increase the accuracy of the detection of the rotation angle θ.

Furthermore, by using a variable scaling parameter A, a cost of calibrating the rotation sensors can be reduced. For example, in the device 10 of the second configuration, the scaling parameter A can be determined using the reference table. By using the reference table, the measurement accuracy of the rotation sensors can be increased over a wider range of applications.

For example, in the device 10 of the third configuration, the scaling parameter A can be determined using the amplitude unit 55 or the temperature unit 60. By using the amplitude unit 55, the scaling parameter A may be determined as a function of the first magnetic field strength B1 and/or the second magnetic field strength B2. By using the temperature unit 60, the scaling parameter A can be determined as a function of the temperature of the barrier layer 20, the fixed layer 25, and/or the free layer 30 detected by the temperature unit 60.

For example, in the device 10 of the third configuration, the scaling parameter A can also be determined using the amplitude unit 55 and the temperature unit 60. By using the amplitude unit 55 and the temperature unit 60, the scaling parameter A can be determined as a function of the first magnetic field strength B1, the second magnetic field strength B2, the sensed temperature of the barrier layer 20, the sensed temperature of the fixed layer 25, and/or the sensed temperature of the free layer 30.

FIG. 7 illustrates a fourth configuration the device 10 for compensating a harmonic in an output voltage U_{MR} of the at least one xMR sensor assembly 12 using at least one calculation module 70. In this fourth configuration of the device 10, the device 10 comprises substantially the components of the first configuration. Further, the fourth configuration of the device comprises the calculation module 70. For example, the calculation module 70 may comprise logic such as a commercially available computer chip for performing calculations. Further, the logic may include a memory unit for caching or storing calculation results.

To compensate the harmonic, the calculation module 70 is electrically connected to the xMR sensor assembly 12. The calculation module 70 is arranged to generate a correction signal in the form of a demodulation voltage U_{DM} from the output voltage U_{MR} of the xMR sensor assembly 12. The calculation module 70 includes at least a demodulation logic 735 and a superposing logic 780.

In the demodulation logic 735, the output voltage U_{MR} of the xMR sensor assembly 12 is converted. This conversion includes generating the demodulation voltage U_{DM}. The calculation module 70 may be a single demodulation logic 735 or may comprise a plurality of separate demodulation logics 735 that are logically interconnected. By using a plurality of demodulation logics 735, it is possible, for example, to compensate the harmonic of different frequencies.

In the fourth configuration of the device 10, the compensating of the harmonic is performed by summing the demodulation voltage U_{DM} and the output voltage U_{MR} in the superposing logic 780. For this compensating of the harmonic, the superposing logic 780 is logically connected to the xMR sensor assembly 12. The superposing logic 780 is arranged to superpose the demodulation voltage U_{DM} on the output voltage U_{MR} of the xMR sensor assembly 12, thereby compensating the harmonic.

The device 10 according to the fourth configuration enables the compensating of the harmonic to be performed, for example, in a computer chip of a motor vehicle. Hereby, the harmonic can be easily compensated in existing motor vehicle structures.

FIG. 8 shows a schematic representation of a fifth configuration of the device 10. In this fifth configuration, the device 10 comprises substantially the components of the fourth configuration and further comprises at least one scaling logic 740. This scaling logic 740 is logically connected to the at least one demodulating logic 735 for compensating the harmonic in the output voltage U_{MR} of the xMR sensor assembly 12. In this fifth configuration, the compensating of the harmonic is performed using a scaling parameter A.

The scaling logic 740 is further logically connected to demodulation logic 735 to compensate the harmonic. The scaling logic 740 is arranged to generate a compensation voltage U_{SK} from the demodulation voltage U_{DM} of the demodulation logic 735 using the scaling parameter A.

The scaling parameter A may be fixed or variable. In the fifth configuration of the device 10 shown in FIG. 8, the scaling parameter A is variable. In the fifth configuration, the scaling parameter A is determined using a reference table. The reference table contains a plurality of fixed defined values in the form of a table. For example, the reference table may contain a corresponding value of the scaling parameter A for the demodulation voltage U_{DM} determined by the demodulation logic 735. This allows to determine the scaling parameter A from the determined demodulation voltage U_{DM}. If the determined value of the demodulation voltage U_{DM} is between or outside the values defined in the reference table, the scaling parameter A is determined, for example, by interpolation from the determined demodulation voltage U_{DM}. The interpolation can, for example, be a linear interpolation between values defined in the reference table. However, higher degree polynomials, a trigonometric interpolation or even a logarithmic interpolation can also be used in the interpolation, for example.

Based on the scaling parameter A determined by the scaling logic 740, the compensation voltage U_{SK} is generated from the demodulation voltage U_{DM} by the scaling logic 740. For compensating of the harmonic, the superposing logic 780 is logically connected to the xMR sensor assembly 12 and the scaling logic 740. The superposing logic 780 is arranged to superpose the compensation voltage U_{SK} on the output voltage U_{MR} of the xMR sensor assembly 12, thereby compensating the harmonic.

The device 10 according to the fifth configuration enables the compensating of the harmonic to be performed, for example, in a computer chip of a motor vehicle. This allows the harmonic to be easily compensated in existing motor vehicle structures. Furthermore, the device 10 according to the fifth configuration makes it possible to determine a scaling parameter for the compensating of the harmonic.

FIG. 9 shows a schematic representation of a sixth configuration of the device 10. The device 10 of the sixth configuration is substantially the same as the device 10 of the fifth configuration. The device 10 of the sixth configuration further comprises at least one of the amplitude unit 55 and the temperature unit 60. In this sixth configuration, the scaling parameter A is variable. In the sixth configuration, determining the scaling parameter A is performed using the amplitude unit 55 and/or the temperature unit 60. The amplitude unit 55 of the sixth configuration of the device 10 is substantially the same as the amplitude unit 55 of the third configuration of the device 10.

The scaling logic unit 740 uses the amplitude |B| determined by the amplitude unit 55 to determine the scaling parameter A. Based on the scaling parameter A determined by the scaling logic 740, the compensation voltage U_{SK} is generated from the demodulation voltage U_{DM} by the scaling logic 740. This compensation voltage U_{SK} is superposed by the superposing logic 780 with the output voltage U_{MR} of the xMR sensor assembly 12 being applied to the superposing logic 780. This compensates the harmonic in the output voltage U_{MR} of the xMR sensor assembly 12.

The temperature unit 60 of the sixth configuration of the device 10 is substantially the same as the temperature unit 60 of the third configuration of the device 10. The scaling logic 740 uses the temperature of the barrier layer 20, the fixed layer 25, and/or the free layer 30 sensed by the temperature unit 60 to determine the scaling parameter A. The scaling logic 740 uses the temperature of the barrier layer 20, the fixed layer 25, and/or the free layer 30 sensed by the temperature unit 60 to determine the scaling parameter A. Based on the scaling parameter A determined by the scaling logic 740, the compensation voltage U_{SK} is generated by the scaling logic 740 from the demodulation voltage U_{DM}. This compensation voltage U_{SK} is superposed by the superposing logic 780 with the output voltage U_{MR} of the xMR sensor assembly 12 being applied to the superposing logic 780. This compensates the harmonic in the output voltage U_{MR} of the xMR sensor assembly 12.

The scaling logic 740 may also use the amplitude |B| detected by the amplitude unit 55 and the temperature detected by the temperature unit 60 of at least one of the barrier layer 20, the fixed layer 25, and/or the free layer 30 to determine the scaling parameter A. Based on the scaling parameter A determined by the scaling logic 740, the compensation voltage U_{SK} is generated from the demodulation voltage U_{DM} by the scaling logic 740. This compensation voltage U_{SK} is superposed by the superposing logic 780 with the output voltage U_{MR} of the xMR sensor assembly 12 being applied to the superposing logic 780.

The device 10 according to the sixth configuration enables the compensating of the harmonic to be performed, for example, in a computer chip of a motor vehicle. This allows the harmonic to be easily compensated in existing motor vehicle structures. Furthermore, the device 10 according to the sixth configuration enables to determine a scaling parameter for the compensating of the harmonic. Furthermore, according to the sixth configuration, the device 10 enables the scaling parameter to be determined as a function of magnetic field strength or temperature.

FIG. 10 shows a process flow diagram depicting a computer-implemented method 300 for compensating the harmonic in the output voltage U_{MR} of the at least one xMR sensor assembly 12. For example, the computer-implemented method 300 is executed on a computer chip of the calculation module 70.

The computer-implemented method 300 relates to compensating of the harmonic by the device 10 according to the fifth configuration or according to the sixth configuration.

The computer-implemented method 300 comprises detecting, in step S300, the output voltage U_{MR} of the xMR sensor assembly 12 in the demodulation logic 735.

The computer-implemented method 300 further comprises converting, in step S310, the output voltage U_{MR} of the xMR sensor assembly 12 in the demodulation logic 735. This converting includes generating the demodulation voltage U_{DM}.

The computer-implemented method 300 further comprises determining the scaling parameter A in step S320.

The computer-implemented method 300 further comprises generating, in step S330, the compensation voltage U_{SK} from the demodulation voltage U_{DM} in the scaling logic 740. Generating the compensation voltage U_{SK} in step S330 is performed using a scaling parameter A.

The computer-implemented method 300 further comprises superposing, in step S340, the compensation voltage U_{SK} with the output voltage U_{MR} of the xMR sensor assembly 12 in the superposing logic 780. This superposing in step S340 compensates the harmonic.

FIG. 11 shows a process flow diagram depicting a computer-implemented method 400 for compensating the harmonic in the output voltage U_{MR} of the at least one xMR sensor assembly 12. For example, the computer-implemented method 400 is executed on a computer chip of the calculation module 70.

The computer-implemented method 400 relates to compensating of the harmonic by the device 10 according to the fourth configuration.

The computer-implemented method 400 comprises detecting, in step S400, the output voltage U_{MR} of the xMR sensor assembly 12 in the demodulation logic 735.

The computer-implemented method 400 further comprises converting, in step S410, the output voltage U_{MR} of the xMR sensor assembly 12 in the demodulation logic 735. This converting includes generating the demodulation voltage U_{DM}.

The computer-implemented method 400 further comprises superposing, in step S420, the compensation voltage U_{SK} with the output voltage U_{MR} of the xMR sensor assembly 12 in the superposing logic 780. This superposing in step S420 compensates the harmonic.

The computer-implemented method further comprises a computer program product, comprising a computer readable hardware storage device having computer readable program code stored therein, said program code executable by a processor of a computer system to implement the method.

Although the present invention has been disclosed in the form of embodiments and variations thereon, it will be understood that numerous additional modifications and variations could be made thereto without departing from the scope of the invention.

For the sake of clarity, it is to be understood that the use of “a” or “an” throughout this application does not exclude a plurality, and “comprising” does not exclude other steps or elements.

### LIST OF REFERENCE SIGNS

10 Device
12 xMR sensor assembly
15 Magnetoresistive element
15a Tunnel magnetoresistive element
15b Giant magnetoresistance element
20 Barrier layer
25 Fixed layer
30 Free layer
35, 735 Demodulation unit
40, 740 Scaling unit
45 Excitation magnet
55 Amplitude unit
60 Temperature unit
65a first Hall sensor
65b second Hall sensor
70 Calculation module
80, 780 Superposing unit/logic
100 Method
A Scaling parameter
U₀ Input voltage
U_{MR} Output voltage
U_{DM} Demodulation voltage
U_{SK} Compensation voltage
Z1 Axis
N North pole
S South pole

1. A method for compensating a harmonic in an output voltage of at least one xMR sensor assembly by a scaling unit, the method comprising:
detecting the output voltage of the at least one xMR sensor assembly in a demodulation unit, wherein the at least one xMR sensor assembly comprises at least one magnetoresistive element;
converting the output voltage of the at least one xMR sensor assembly in the demodulation unit, wherein the converting comprises generating a demodulation voltage;
generating a compensation voltage from the demodulation voltage in the scaling unit, wherein the generating of the compensation voltage is performed using a scaling parameter; and
compensating the harmonic by superposing the compensation voltage with the output voltage of the at least one xMR sensor assembly in a superposing unit.

2. The method of claim 1, further comprising:
determining the scaling parameter.

3. The method according to claim 2, wherein:
the determining of the scaling parameter is performed using an amplitude unit.

4. The method according to claim 2, wherein:
the determining of the scaling parameter comprises comparing a first magnetic field strength detected by a first Hall sensor and a second magnetic field strength detected by a second Hall sensor.

5. The method according to claim 2, wherein:
the determining of the scaling parameter comprises comparing a first magnetic field strength detected by a first Hall sensor or a second magnetic field strength detected by a second Hall sensor.

6. The method according to claim 3, wherein:
the determining of the scaling parameter comprises comparing a first magnetic field strength detected by a first Hall sensor and a second magnetic field strength detected by a second Hall sensor.

7. The method according to claim 3, wherein:
the determining of the scaling parameter comprises comparing a first magnetic field strength detected by a first Hall sensor or a second magnetic field strength detected by a second Hall sensor.

8. The method according to claim 2, wherein:
the determining of the scaling parameter is performed using the temperature unit, wherein the determining of the scaling parameter comprises determining a temperature of at least one of the at least one xMR sensor assembly.

9. The method according to claim 8, wherein:
the determining of the temperature of at least one of the at least one xMR sensor assembly comprises sensing a temperature of the magnetoresistive element, wherein
the detecting of the temperature of the magnetoresistive element comprises detecting a temperature of at least one of a barrier layer, a fixed layer or a free layer of the magnetoresistive element.

10. A method for compensating a harmonic in an output voltage of at least one xMR sensor assembly, the method comprising:
detecting the output voltage of the at least one xMR sensor assembly in a demodulation unit, wherein the at least one xMR sensor assembly comprises at least one magnetoresistive element;
converting the output voltage of the at least one xMR sensor assembly in the demodulation unit, wherein the converting comprises generating a demodulation voltage; and
compensating the harmonic by superposing the demodulation voltage with the output voltage of the at least one xMR sensor assembly in a superposing unit.

11. A device for compensating a harmonic in an output voltage of at least one xMR sensor assembly, the device comprising:
the at least one xMR sensor assembly comprising at least one magnetoresistive element, wherein the at least one magnetoresistive element comprises a barrier layer, a fixed layer, and a free layer, and wherein the barrier layer is arranged between the free layer and the fixed layer, and wherein the at least one xMR sensor assembly has the output voltage;
at least one excitation magnet;
at least one demodulation unit electrically connected to the at least one xMR sensor assembly, wherein the demodulation unit is arranged to generate a demodulation voltage by converting the output voltage of the at least one xMR sensor assembly;
a scaling unit electrically connected to the demodulation unit, the scaling unit being arranged to generate a compensation voltage using a scaling parameter; and
a superposing unit electrically connected to the at least one xMR sensor assembly and the scaling unit, wherein the superposing unit is arranged to superpose the compensation voltage with the output voltage of the at least one xMR sensor assembly.

12. The device according to claim 11, wherein
the barrier layer, the fixed layer, and the free layer are arranged along an axis; and
the excitation magnet is arranged along the axis.

13. The device according to claim 11, wherein
the fixed layer comprises a ferromagnet.

14. The device according to claim 11, in which
the free layer comprises a permanent magnet.

15. The device according to claim 11, in which
the excitation magnet is arranged rotatable about an axis relative to the at least one xMR sensor assembly.

16. The device according to claim 11, wherein
the at least one demodulation unit comprises a plurality of separate demodulation units.

17. The device according to claim 11, wherein
the scaling parameter is fixedly defined.

18. The device according to claim 11, in which
the scaling parameter is variable, and
the scaling unit determines the scaling parameter using at least one of an amplitude unit and a temperature unit.

19. The device according to claim 11, wherein
the amplitude unit comprises at least a first Hall sensor and a second Hall sensor.

20. A device for compensating a harmonic in an output voltage of at least one xMR sensor assembly, the device comprising:
the at least one xMR sensor assembly comprising at least one magnetoresistive element, wherein the at least one magnetoresistive element comprises a barrier layer, a fixed layer, and a free layer, and wherein the barrier layer is arranged between the free layer and the fixed layer, and wherein the at least one xMR sensor assembly has the output voltage;
at least one excitation magnet;
at least one demodulation logic logically connected to the at least one xMR sensor assembly, wherein the demodulation logic is arranged to generate a demodulation voltage by converting the output voltage of the at least one xMR sensor assembly;
a scaling logic logically connected to the demodulation logic, the scaling logic being arranged to generate a compensation voltage using a scaling parameter; and
a superposing logic logically connected to the at least one xMR sensor assembly and the scaling logic, wherein the superposing logic is arranged to superpose the compensation voltage with the output voltage of the at least one xMR sensor assembly.

21. A computer-implemented method for compensating a harmonic in an output voltage of at least one xMR sensor assembly by a scaling logic, the computer-implemented method comprising:
detecting the output voltage of the at least one xMR sensor assembly in a demodulation logic, wherein the at least one xMR sensor assembly comprises at least one magnetoresistive element;
converting the output voltage of the at least one xMR sensor assembly in the demodulation logic, wherein the converting comprises generating a demodulation voltage;
generating a compensation voltage from the demodulation voltage in the scaling unit, wherein the generating of the compensation voltage is performed using a scaling parameter; and
compensating the harmonic by superposing the compensation voltage on the output voltage of the at least one xMR sensor assembly in a superposing logic.

22. A computer-implemented method for compensating a harmonic in an output voltage of at least one xMR sensor assembly, the method comprising:
detecting the output voltage of the at least one xMR sensor assembly in a demodulation logic, wherein the at least one xMR sensor assembly comprises at least one magnetoresistive element;
converting the output voltage of the at least one xMR sensor assembly in the demodulation logic, wherein the converting comprises generating a demodulation voltage; and
compensating the harmonic by superposing the demodulation voltage with the output voltage of the at least one xMR sensor assembly in a superposing logic.

23. A computer program product, comprising a computer readable hardware storage device having computer readable program code stored therein, said program code executable by a processor of a computer system to implement the method as claimed in claim 1.
